(19) United States
(12) Patent Application Publication
(10) Pub. No.: US 2007/0205844 A1
(43) Pub. Date: Sep. 6, 2007

(54) Frequency Multiplying Arrangements and a Method for Frequency Multiplication

(75) Inventor: Herbert Zirath, Mölndal (SE)

Correspondence Address: POTOMAC PATENT GROUP, PLLC, P. O. BOX 270, FREDERICKSBURG, VA, 22404, US

(73) Assignee: TELEFONAKTIEBOLAGET L M ERICSSON (PUBL), SE-164 83 Stockholm (SE)

(21) Appl. No.: 10/596,609

(22) PCT Filed: Dec. 19, 2003
(86) PCT No.: PCT/SE03/02017

§ 371 Date: Apr. 7, 2007

(51) Int. Cl. H03C 3/38

(52) U.S. Cl. 332/120

(57) ABSTRACT

The present invention relates to a frequency multiplying arrangement (10) comprising a transistor arrangement with a first and a second transistor (T1, T2), each with an emitter (e), a base (b) and a collector (c), a voltage (current) source, output means for extracting an output signal (Vₒᵤₜ) comprising a multiplied output frequency harmonic of an input signal (Vᵢₙ), and impedance means. The impedance means comprises a first impedance means (3) connected to the collectors of the respective transistors, the transistors operating in phase opposition, and the waveform of the current for each transistor is half wave shaped such that the transistor is conducting only the half of each period, and the output signal (Vₒᵤₜ) is extracted (P) between the first impedance means (3; 3₁; 3₂; 3₃; 3₄; 3₅) and the collectors (c) of the transistors.

### FIELD OF THE INVENTION

The present invention relates to a frequency multiplying arrangement, comprising a transistor arrangement, a current (voltage) source, first impedance means and output means for extracting an output signal comprising a multiplied frequency harmonic of an input signal. The invention also relates to a method for multiplying, e.g. doubling, the frequency of a signal input to an arrangement.

### STATE OF THE ART

Circuits for frequency generation are fundamental within communication systems, radio systems or radiometer systems. A frequency synthesizer is a circuit generating a very precise, temperature stable frequency according to an external reference frequency. Most of the time the frequency also must have a constant phase difference with respect to the reference signal. For example a multi-standard frequency synthesizer must be able to synthesize different bands of frequencies for for example different wireless standards within telecommunications. A multiband frequency synthesizer often has to be able to synthesize a wide range of frequencies while still satisfying strict phase noise specifications. Single-band frequency synthesizers are commonly used to synthesize a narrow frequency band whereas multiband frequency synthesizers are needed to synthesize multiple frequency bands. Generally there can be said to be three different types of frequency synthesizers, namely the table look-up synthesizer, the direct synthesizer and the indirect or phase locked synthesizer. Today it is aimed at achieving low cost, fully integrated frequency synthesizers, which however is quite difficult since the different components involved, such as low pass filters etc. normality have to be external due to noise requirements etc. Most synthesizers used in mobile telecommunication systems are of the type Phase Locked Loop synthesizers, in the following denoted PLL synthesizers. The reference frequency, which generally is a low frequency, is multiplied by a variable integer (sometimes a fraction of a) number. This is achieved by dividing the output frequency for that number, and adjusting the output frequency such that the divided frequency will equal the reference frequency. Thus, often the frequency generated by the oscillator has to be multiplied by a number N in order to achieve the desired frequency.

It is known to perform both a frequency generation functionality by means of an oscillator and a frequency multiplication by means of one circuit, for example an oscillator at the same time used as a frequency multiplier. However, the conversion of the reference frequency to the multiplied frequency, e.g. the double frequency, is often inefficient and a lot of amplifying circuitry is generally needed and, as referred to above, it may be difficult to provide an integrated circuit.

It is known to use two balanced transistors to obtain a doubled frequency when extracting an output signal over the emitter. At the emitter node the currents on the double frequency are in phase and can thus be extracted over an external load or impedance. However, generally the amplitude is low and it mostly needs to be amplified.

U.S. Pat. No. 4,810,976 shows an oscillator which is balanced and in which a resonant impedance network is connected between the control ports of two matched transistors. A capacity is connected in parallel across the two inputs of the transistors. The inputs of the transistors are connected to a matched current source respectively. The signals at the transistor outputs are summed together at a common node. The signals of resonant frequency in each arm of the oscillator are equal in magnitude but opposite in phase. This means that the signals cancel at the resonant frequency, whereas signals at the second harmonic frequency add constructively and thus are enhanced. The effect will be a net frequency doubling. For high frequency operation bipolar transistors are utilized. However, also this arrangement suffers from the drawbacks referred to above.

FIG. 1 shows a state of the art balanced amplifier used as a frequency doubler. The two transistors operate in anti-phase and a load is taken out at the emitters of the transistors. The amplitude of the voltage extracted at the double frequency will be quite low for such a circuit due to the fact that the capacitor located after the emitters of the transistors will short-circuit higher frequencies, which is disadvantageous.

FIG. 2, which is a state of the art figure, shows a so called Colpitt oscillator illustrating two transistors operating in anti-phase. The load is taken out at either of the collectors of the transistors. This will also result in a comparatively low amplitude for the extracted voltage at the double frequency due to the fact that the resonant circuit will short-circuit harmonic overtones.

### SUMMARY OF THE INVENTION

What is needed is therefore a frequency multiplying arrangement as initially referred to for the which the conversion of the reference frequency to a multiple frequency, or particularly to the double frequency, is efficient, particularly such that amplifying circuitry is avoided to an extent which is as high as possible, or even more particularly, completely. Furthermore an arrangement is needed which can be fabricated as a small sized integrated circuit, particularly as a Monolithic Microwave Integrated Circuit (MMIC). Particularly an oscillator is needed through which one or more of the above mentioned objects can be fulfilled. Particularly, an amplifier is needed through which one or more of the above mentioned objects can be achieved. Still further an arrangement is needed through which different kinds of transistors can be used while still allowing fulfillment of providing the objects referred to above.

A method for frequency multiplication is therefore also needed through which one or more of the above mentioned objects can be achieved.

Therefore an arrangement having the characterizing features of claim 1 is provided. A method is also provided having the characterizing features of claim 20. Advantageous or preferred embodiments are given by the appended subclaims.

According to the invention it is thus provided a frequency multiplying arrangement comprising a transistor arrangement with a first and a second transistor, each with an emitter, a base and a collector, a voltage source, output means for extracting an output signal comprising a multiplied output frequency harmonic of an input signal, and impedance means. The impedance means comprises a first impedance means connected to the collectors of the respective transistors, the transistors operating in phase opposition. The waveform of the current for each transistor is half wave shaped such that the transistor is conducting only the half of each period, and the output signal is extracted between the first impedance means and the collectors of the transistors.

In one embodiment the first impedance means comprises an inductor. In another embodiment the first impedance means comprises a resistor. Particularly the collectors of the two transistors are interconnected.

Advantageously the waveform of the current through the transistors is clipped sinusoidal, e.g. half sine/cosine shaped. The sine/cosine shaped includes square sine/cosine shapes. Particularly the output signal is extracted as a voltage drop over said first impedance. In advantageous implementation the first harmonic collector currents of the first and second transistors are 180° out of phase with respect to one another, and for even harmonics, the signals from the respective first and second transistors are in phase. The transistors may be bipolar transistors. Alternatively the transistors are FETs. The impedance means may further comprise second impedance means, said first impedance being connected in series with said second impedance means.

Even more particularly said second impedance means comprises a first inductor and a second inductor respectively each connected to a collector of the respective transistors, the output signal being extracted between, e.g. at the junction node between the first impedance means and the second impedance means. Further yet the second impedance means may comprise a collector circuit comprising a transformer comprising said two inductors, the output signal being extracted between said inductors, i.e. at the mid-output of the transformer.

Said mid-output particularly acts as a virtual short-circuit for odd frequencies, and an output is e.g. extracted at the mid-point as a voltage drop over the first impedance means, e.g. an inductor or a resistor.

The arrangement may comprise a balanced frequency multiplying amplifier, e.g. a frequency doubling amplifier. The arrangement may also comprise an oscillator. Particularly the oscillator comprises a Colpitt oscillator. The arrangement is in preferable embodiments implemented as a MMIC (Monolithic Microwave Integrated Circuit).

The invention also provides a method of multiplying, e.g. doubling, a reference frequency by means of an arrangement comprising a transistor arrangement with a first and a second transistor, each with an emitter, a base and a collector, and a current (voltage) source. It comprises the steps of; feeding a signal to a first and second transistor the collectors of which being 180° out of phase with respect to each other; adding the out of phase signals in an external circuit; extracting a multiplied, e.g. doubled, harmonic of the input signal over a first impedance means connected to the collectors of the transistors or connected in series with second impedance means connected to the collectors. The first impedance means may comprise an inductor or a resistor. Particularly the second impedance means comprises two inductors, each connected to a collector of the respective transistors, the output signal being extracted at the junction between the first and second impedance means.

### BRIEF DESCRIPTION OF THE DRAWINGS

The invention will in the following be more thoroughly described, in a non-limiting manner, and with reference to the accompanying drawings, in which:

FIG. 1 shows a state of the art balanced amplifier used as a frequency doubler,

FIG. 2 shows a state of the art Colpitt oscillator used as a frequency doubler,

FIG. 3 shows, in a simplified manner, a circuit for providing a multiplied (doubled) frequency according to one implementation of the invention,

FIG. 4 shows, in a simplified manner, a circuit for providing a multiplied (doubled) frequency according to another implementation of the invention,

FIG. 5 shows, in a simplified manner, a circuit for providing a multiplied (double) frequency according to a third implementation of the invention,

FIG. 6 shows a balanced amplifier, according to one implementation of the invention, which is used as a frequency multiplier,

FIG. 7 shows an oscillator (a Colpitt oscillator) used for frequency multiplication according to another embodiment of the present invention,

FIG. 8 shows somewhat more in detail an example on a circuit according to the present invention, similar e.g. to the circuit of FIG. 3,

FIG. 9A shows the waveform for the voltage of the collector of a first transistor as in FIG. 8,

FIG. 9B shows the waveform for the voltage of the collector of a second transistor as in FIG. 8,

FIG. 9C shows the waveform of the collector current for a first transistor as in FIG. 8,

FIG. 9D shows the waveform of the collector current for a second transistor as in FIG. 8,

FIG. 10A shows the waveform of the emitter voltage of a transistor as in arrangement of FIG. 8,

FIG. 10B shows the waveform of the base voltage of a transistor as in FIG. 8, and

FIG. 10C shows the waveform of the extracted output voltage of an arrangement as in FIG. 8.

### DETAILED DESCRIPTION OF THE INVENTION

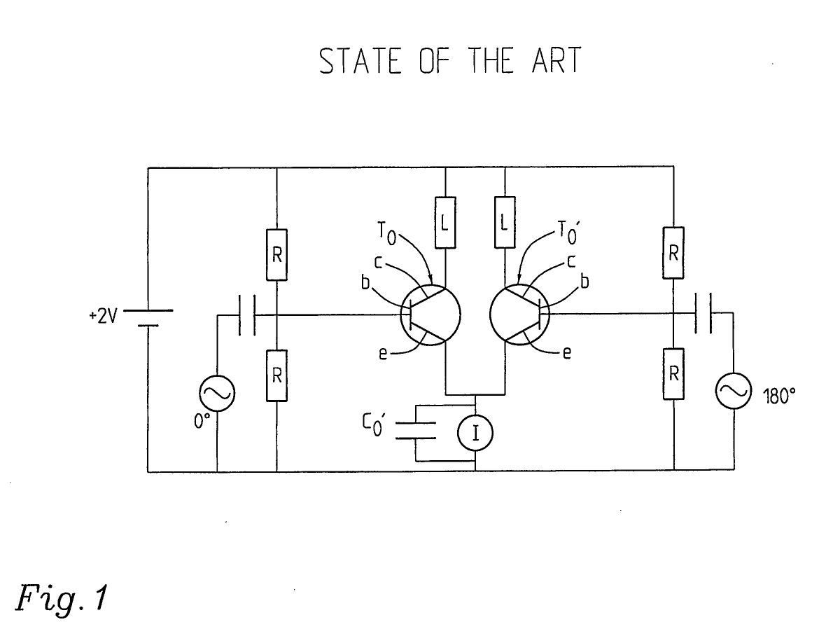

FIG. 1 shows a known balanced amplifier, here used as a frequency doubler. The two transistors T₀, T₀′ operate in antiphase, i.e. signals applied to the bases of the transistors are maintained in antiphase. The output signal is taken out at the emitters. With this circuit the extracted output voltage gets a low amplitude at the doubled frequency (2×f₀) among others due to the capacitor C₀′ after the emitters of the respective transistors acting as a short-circuit for higher frequencies, which is a clear disadvantage.

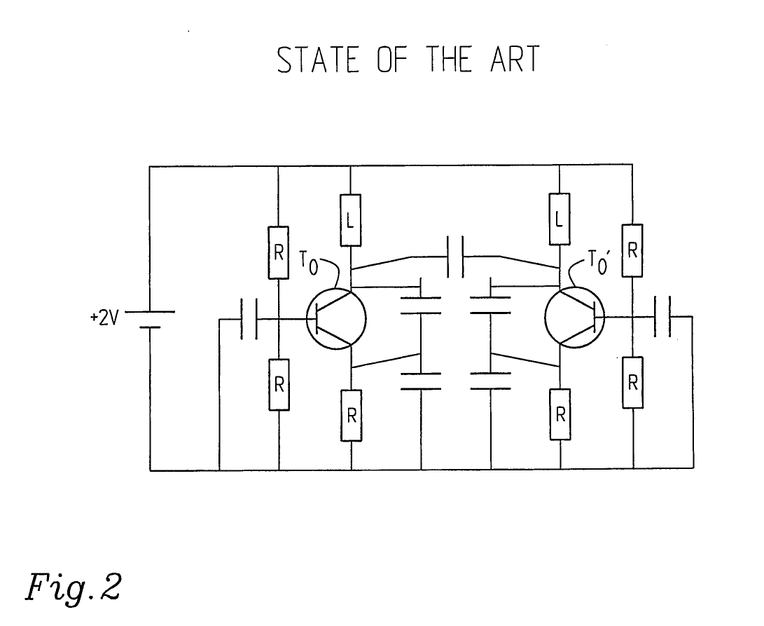

FIG. 2 shows a known Colpitt oscillator. The two transistors (also here denoted T₀, T₀′) in such an oscillator operate in antiphase. The output signal is extracted at the collector of one of the transistors. The amplitude of the output (extracted) voltage will be relatively low at twice the input (reference) frequency (2×f₀), since the resonance circuit will act as a short-circuit for harmonics/overtones.

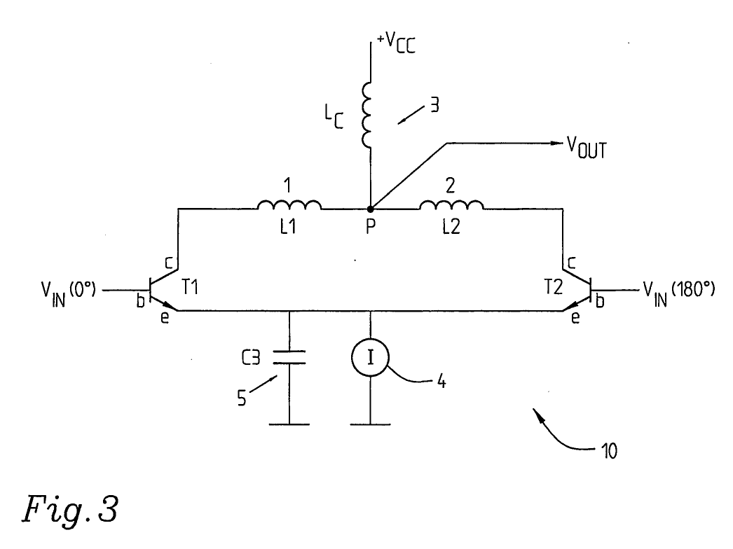

FIG. 3 is a simplified circuit diagram illustrating one implementation of the inventive concept. The circuit of FIG. 3 shows an arrangement 10 comprising a first transistor T1 and a second transistor T2. An input voltage V1ᵢₙ (0°) is provided to T1 and an input voltage V2ᵢₙ (180°) is provided to T2, wherein V1ᵢₙ and V2ᵢₙ are similar but differ 180° in phase in relation to one another. T1 and T2 each comprises a base b, an emitter e and a collector c. It is here supposed that second impedance means are provided comprising two connected inductors L1 1, L2 2, here a transformer with a mid-extraction point P. The mid-extraction point P will here act as a short circuit for odd frequencies since there is an excitation of an odd mode between the collectors c (T1) and c (T2), i.e. they are 180° out of phase. For even overtones even modes are obtained, i.e. the signals are in phase, and even overtones are added. The fundamental frequency component will be substantially cancelled. At the mid-point there will be currents at even frequencies, even harmonics are enhanced, as referred to above, which here are extracted as a voltage drop Vₒᵤₜ (nf) (wherein n e.g. =2, i.e. at the doubled frequency) over first impedance means 3, here comprising an inductor L_{c} 3. The amplitude of the output voltage Vₒᵤₜ is much higher than a voltage extracted across the emitter (as it is done in prior art).

The current generator 4 is used to set the operation current of the transistors T1, T2 and the capacitor C3 5 is used to ground the emitters (for providing e.g. half cosine shaped pulses).

Since the currents are out of phase, there will be no current at the fundamental frequency.

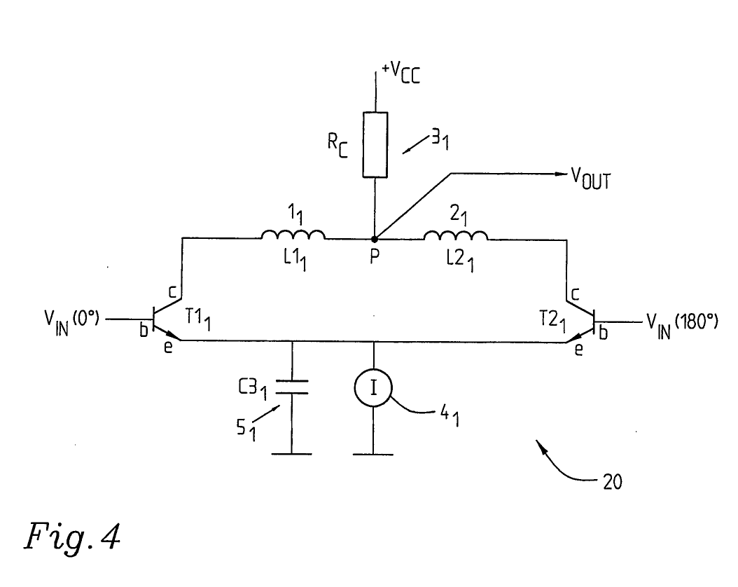

FIG. 4 shows another implementation of the inventive concept in the form of an amplifying and multiplying arrangement 20. The circuit diagram is similar to that of FIG. 3, with the difference that a resistor R_{c} 3₁ is used as first impedance means. In other aspects the functioning is similar, and similar reference numerals provided with an index 1 are used for corresponding components.

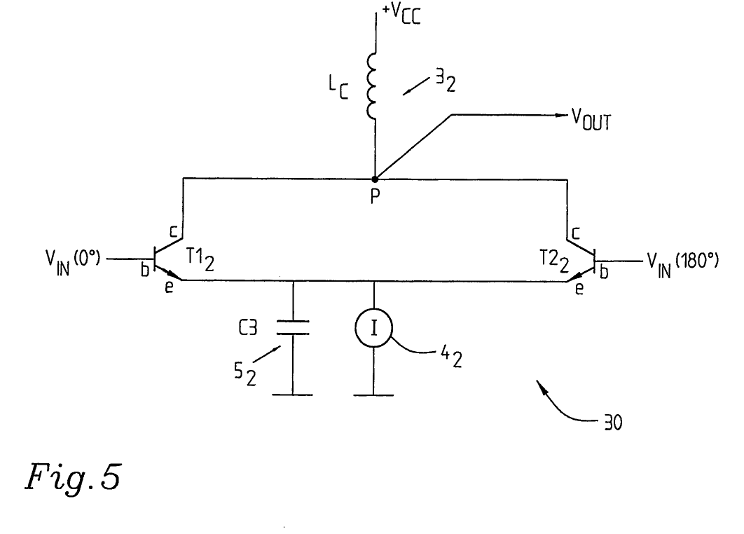

FIG. 5 shows still another embodiment of the present invention. It relates to an amplifying and multiplying arrangement 30 with two transistors T1₂, T2₂ wherein Vᵢₙ to T1₂ and T2₂ respectively is 180° out of phase. The difference is here that the collectors of T1₂ and T2₂ respectively are connected directly to each other and there are no second impedance means, but the output voltage Vₒᵤₜ is extracted at the junction where the two collectors are connected, over the first impedance means, here an inductor L_{c} 3₂.

Components similar to those of FIGS. 3, 4 are given the same reference numerals with index 2.

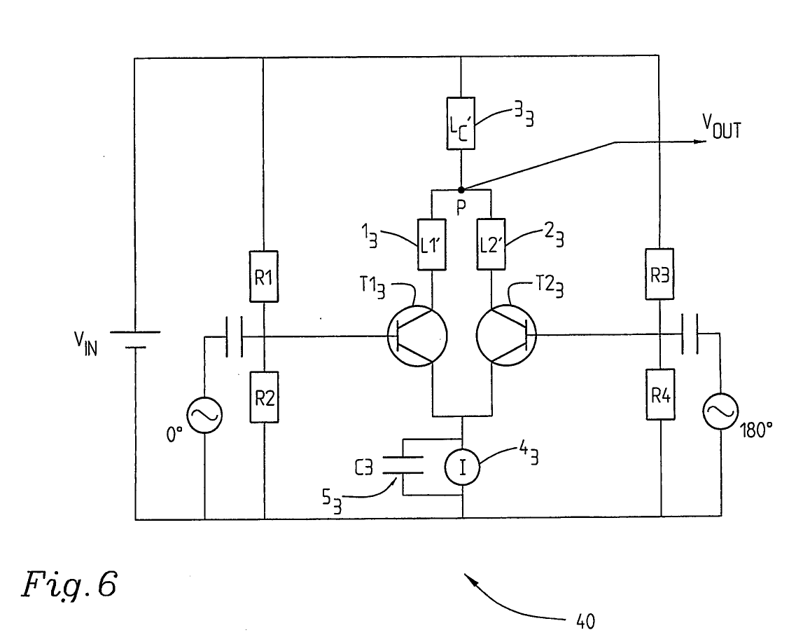

FIG. 6 shows somewhat more in detail an embodiment of an amplifier 40 substantially similar to that disclosed in FIG. 3. Similar components are given similar reference numerals with index 3. A voltage source is used to provide the input voltage Vᵢₙ, and tone generators (0°, 180°) are used to provide input voltages differing 180° in phase to two transistors T1₃, T2₃. Resistors R1-R4 are used to bias the transistors T1₃, T2₃ in a conventional manner. A capacitor C3 5₃ is used to connect the emitters of the transistors to ground such that a half cosine pulse shaped waveform with a lot of (enhanced) harmonics, particularly even harmonics can be provided). The first impedance means L_{c}′ 3₃ comprises an inductor connected in series with second impedance means L1′ 1₃, L2′ 2₃ connected to the collectors of the respective transistors T1₃, T2₃. The output signal Vₒᵤₜ (e.g. V (2f_{ref})) is extracted over the first impedance means L₀′ 3₃, i.e. before the second impedance means L1′ 1₃, L2′ 2₃, e.g. at the junction node P between the first 3₃ and second 1₃, 2₃ impedance means. In other aspects the functioning is similar to that described above.

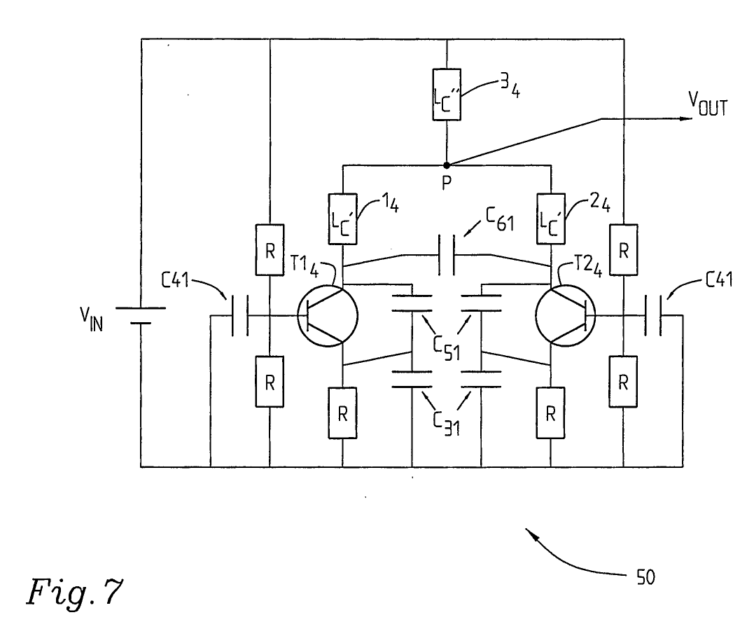

FIG. 7 shows still another implementation of the present invention comprising an oscillator with a frequency multiplying functionality 50 two transistors T1₄, T2₄ operating in anti-phase. The oscillator comprises a so called Colpitt oscillator. Capacitors C₃₁, C₃₁ are used to ground the emitters of the transistors T1₄, T2₄ whereas capacitors C₄₁, C₄L are used to ground the bases of the transistors T1₄, T2₄. Capacitor C₆₁ forms part of a resonant circuit comprising second impedance means L₂₁ 1₄, L₃₁ 2₄ such that the inductors 1₄, 2₄ and the capacitor C₆₁ form a parallel resonant circuit for the oscillator. The output voltage Vₒᵤₜ is extracted at the node between the first impedance means consisting of inductor L_{c}″ 3₄ and the second impedance means comprising the resonant circuit. The resistors all denoted R function in a manner similar to that of prior art arrangements and will therefore not be further described herein. Capacitors C₅₁, C₅₁ are feedback capacitors.

Like in the arrangements comprising amplifiers, the transistors operate in anti-phase. In an arrangement as discussed herein above, there will be a higher current through collector-emitter and since the transistors operate in anti-phase, half-wave wave forms are provided and even harmonics are enhanced whereas the fundamental frequency is cancelled. Since Vₒᵤₜ is extracted over the first impedance means 3₄, at the junction between the first and second impedance means, the voltage that can be extracted will be very much higher than in known arrangements where the output voltage is extracted over the emitters.

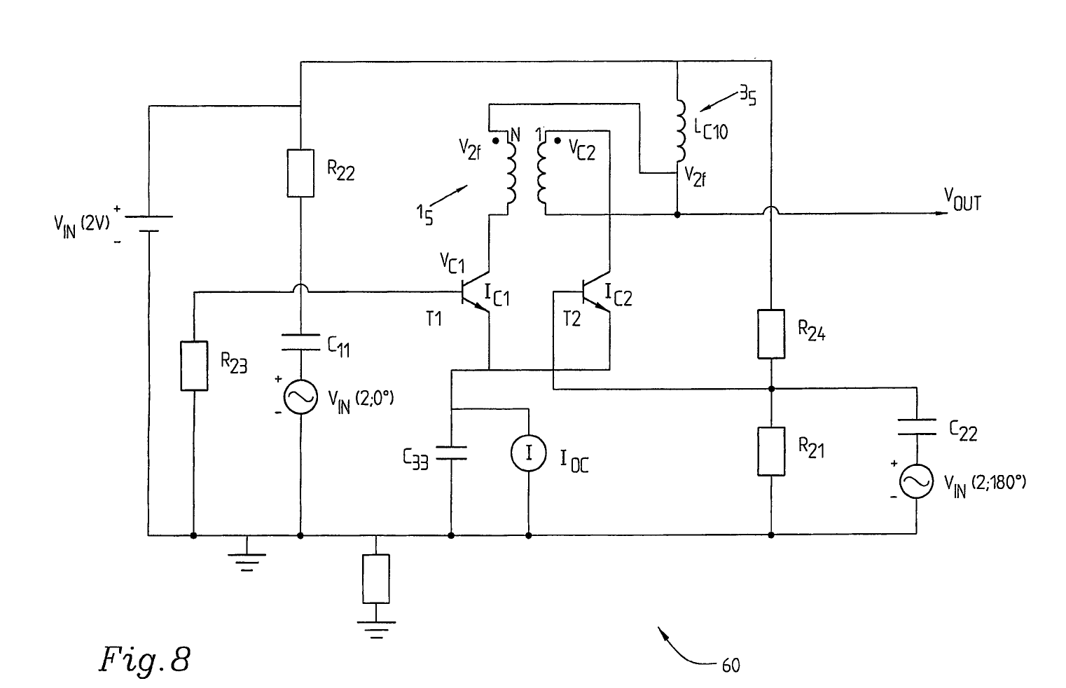

FIG. 8 is a somewhat more detailed illustration of an arrangement according to the invention which shows a frequency multiplying amplifier 60.

An input voltage Vᵢₙ (DC) of 2[V] is here used. Of course other voltages can be used. For exemplifying, by no means limiting, reasons, numerical values are given for the different components etc. As in the embodiments described in the foregoing, the arrangement 60 comprises a first and a second transistor T1, T2 respectively. A DC supply voltage of 2 Volts is, as referred to above, used and Vᵢₙ (2V, 0°) is supplied to T1, whereas Vᵢₙ (2V, 180°) is supplied to T2, i.e. the input supply voltages are 180° out of phase with respect to one another. Resistors R₂₁, R₂₂, R₂₃, R₂₄ are used for biasing the transistors T1, T2. Also capacitors C₁₁, C₂₁ are used for biasing the transistors. R₂₂ may have a resistance of e.g. 5 kΩ, R₂₃ of 5.2 kΩ, R₂₁ of 5.2 kΩ and R₂₄ of 5kΩ, whereas C₁₁, C₂₂ each may have a capacitance of 1,0 μF. C₃₃ may have a capacitance of 2 pF and it is used to ground the emitters of T1 and T2 such that the waveform will be half-wave shaped, e.g. comprise a half cosine pulse. As referred to earlier in the application, the output signal will have much overtones (the fundamental component being suppressed), particularly even harmonics, which are added, which is exceedingly advantageous. I_{DC} may comprise 8 [mA].

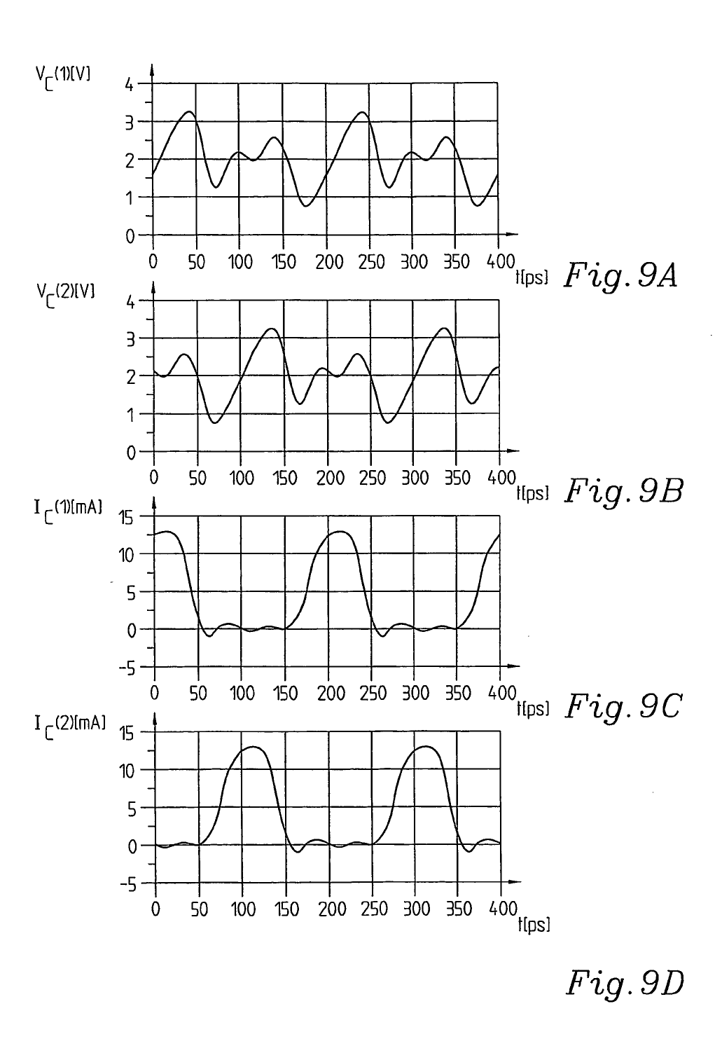

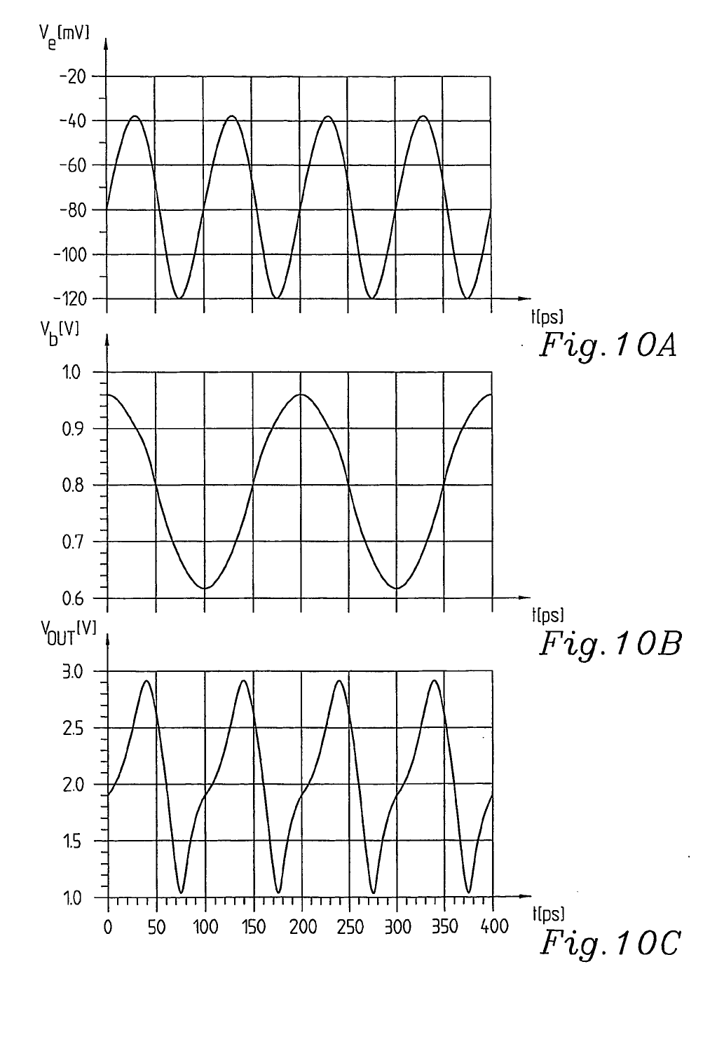

V_{base} indicates the voltage over the transistor bases (cf. FIG. 10B). V_{c1}, V_{c2} indicate the collector voltages, cf. FIGS. 9A, 9B and Vₑ is the emitter voltage (cf. FIG. 10A). I_{c1} and I_{c2} indicate the collector currents of T1 and T2 respectively, cf. FIGS. 9C, 9D. FIGS. 9A-9D, 10A-10C below illustrate the waveforms of the signals in an arrangement similar to that described above with reference to FIG. 8. Particularly FIG. 10C illustrates Vₒᵤₜ, i.e. the extracted output voltage (at, here, doubled frequency).

1₂₁ indicates (FIG. 8) the second impedance means, here comprising a transformer connected to the collectors of T1 and T2. In series with said transformer 1₂₁ first impedance means inductor L_{c10} are connected over which Vₒᵤₜ is extracted (cf. also FIG. 10C). L_{c10} here e.g. has an inductance of 20 nH.

In FIGS. 9A-9D, 10A-10C signal waveforms are illustrated in diagrams for an embodiment in which Vᵢₙ=200 mV, Ie=4 mA, Ce=2 pF and the transformer inductance L=2 nH.

FIGS. 9A, 9B show the waveforms for the collector voltages V_{c1}, V_{c2} for T1 and T2 respectively in [V] as a function of time (in ps).

FIGS. 9C, 9D illustrate the collector currents I_{c1}, I_{c2} in [mA] as a function of time (in [ps]) for T1 and T2 respectively. As can be seen the signals, comprise half cosine pulses; half of the cycle is zero and therebetween (or the remainder of the signals) is sine/cosine shaped. Thus, there are a lot of overtones (even), which are added, and these currents are attractive for extraction.

FIG. 10A shows the variation in emitter voltage in [mV] as a function of time (in ps). As can be seen from the figure, the emitter peak-to-peak voltage is 80 mV.

FIG. 10B shows the transistor base voltage [V] as a function of time in [ps]. Finally FIG. 10C shows the extracted output voltage Vₒᵤₜ in [V] as a function of time in [ps], i.e. the voltage of the multiplied (here doubled) frequency signal. As referred to earlier in the application it is particularly the output voltage (Vₒᵤₜ) in the node junction between the first and the second impedance means. The amplitude of the signal Vₚ₋ₚ (V peak-to-peak)=1.9 [V] as can be seen from FIG. 10C. The conversion gain G_{c} will then be 1.9 [V]/0.4 [V]≈5; 0.4 being 2×0.2, wherein 0.2 is the amplitude of the input signal, i.e. the sum of the amplitudes of the two input signals will be 0.4. For a corresponding, conventional arrangement the conversion gain would be approximately 0.15/0.4≈0.4 i.e. Vₒᵤₜ=0.15 [V], and G_{c} of an arrangement according to the present invention would (in this particular embodiment) thus be more than 10 times the conversion gain G_{c} of an arrangement in which the output voltage is extracted over the emitter.

Although it is mainly referred to a frequency doubled signal, it should be clear that also other (even) overtones (harmonics) are provided, and summed, whereas the fundamental component is cancelled, as well as odd overtones.

Particularly the arrangement is implemented as a Monolithic Microwave Integrated Circuit (MMIC).

Different kinds of transistors can be used, e.g. bipolar transistor, FETs etc. According to the invention a signal of 2× the reference frequency (or an even factor × the reference frequency) can be extracted at virtual ground of the resonant circuit in the case of an oscillator (or an amplifier).

It should be clear that the invention of course not is limited to the explicitly illustrated embodiments, but that it can be varied in a number of ways within the scope of the appended claims.

1-23. (canceled)

24. A frequency multiplying arrangement, comprising:
a transistor arrangement, including:
a first transistor and a second transistor, each of the first and second transistors having an emitter, a base, and a collector;
a voltage source or a current source;
output means for extracting an output signal that comprises a multiplied output frequency harmonic of an input signal; and
impedance means, comprising a first impedance means connected to the collectors of the first and second transistors; wherein the first and second transistors operate in phase opposition; a waveform of a current for each transistor is half-wave shaped such that the respective transistor conducts during only half of each period of the waveform; and the output signal is extracted between the first impedance means and the collectors of the first and second transistors.

25. The arrangement of claim 24, wherein the first impedance means comprises an inductor.

26. The arrangement of claim 24, wherein the first impedance means comprises a resistor.

27. The arrangement of claim 24, wherein the collectors of the first and second transistors are interconnected.

28. The arrangement of claim 24, wherein the waveform of the current for each transistor has a clipped sinusoidal shape.

29. The arrangement of claim 24, wherein the output signal is extracted as a voltage drop across the first impedance means.

30. The arrangement of claim 24, wherein first harmonics of collector currents of the first and second transistors are 180 degrees out of phase with respect to each another.

31. The arrangement of claim 30, wherein even harmonics of signals from the first and second transistors are in phase with respect to each other.

32. The arrangement of claim 24, wherein the first and second transistors are bipolar transistors.

33. The arrangement of claim 24, wherein the first and second transistors are field-effect transistors.

34. The arrangement of claim 24, wherein the impedance means further includes second impedance means, and the first impedance means is connected in series with the second impedance means.

35. The arrangement of claim 34, wherein the second impedance means comprises a first inductor and a second inductor; each of the first and second inductors is connected to a collector of a respective one of the first and second transistors; and the output signal is extracted between the first impedance means and the second impedance means.

36. The arrangement of claim 35, wherein the second impedance means comprises a collector circuit comprising a transformer comprising the first and second inductors, and the output signal is extracted between the first and second inductors at a mid-point of the transformer.

37. The arrangement of claim 36, wherein the mid-point acts as a virtual short-circuit for odd harmonics.

38. The arrangement of claim 37, wherein the output signal is extracted at the mid-point as a voltage drop across the first impedance means.

39. The arrangement of claim 24, further comprising a balanced frequency-multiplying amplifier.

40. The arrangement of claim 35, further comprising an oscillator.

41. The arrangement of claim 40, wherein the oscillator comprises a Colpitts oscillator.

42. The arrangement of claim 24, wherein the arrangement is implemented as a monolithic microwave integrated circuit.

43. A method of multiplying a reference frequency by an arrangement comprising a transistor arrangement having a first transistor and a second transistor, each of the first and second transistors having an emitter, a base and a collector; and a current source or a voltage source, the method comprising the steps of:
feeding an input signal to the first and second transistors, the collectors of which are 180 degrees out of phase with respect to each other;
adding out-of-phase signals from the collectors in an external circuit; and
extracting a multiplied harmonic of the input signal across a first impedance means that is either connected to the collectors of the first and second transistors or connected in series with a second impedance means connected to the collectors of the first and second transistors.

44. The method of claim 43, wherein the first impedance means comprises an inductor.

45. The method of claim 43, wherein the first impedance means comprises a resistor.

46. The method of claim 44, wherein the second impedance means comprises two inductors; each of the two inductors is connected to the collector of a respective one of the first and second transistors; and the output signal is extracted at a junction between the first and second impedance means.
